(19) United States
(12) Patent Application Publication
(10) Pub. No.: US 2001/0042867 A1
(43) Pub. Date: Nov. 22, 2001

(54) Monolithic compound semiconductor integrated circuit and method of forming the same

(75) Inventor: Naoki Furuhata, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/848,263

(22) Filed: May 4, 2001

(30) Foreign Application Priority Data
May 17, 2000 (JP) 2000-149797

(51) Int. Cl. H01L 31/0328; H01L 21/331; H01L 27/102; H01L 29/70

(52) U.S. Cl. 257/197; 257/198; 438/235; 438/309; 438/312; 438/317; 257/571; 257/577; 438/328

(57) ABSTRACT

A monolithically integrated semiconductor device comprises: a hetero-junction bipolar transistor having at least an electrode contact layer which contacts directly with at least one of collector, base and emitter electrodes; and at least a passive device having at least a passive device electrode and at least a resistive layer, wherein the electrode contact layer and the resistive layer comprise the same compound semiconductor layer.

### BACKGROUND OF THE INVENTION

1. Field of the Invention

The present invention relates to a compound semiconductor integrated circuit and a method of forming the same, and more particularly to a monolithic microwave integrated circuit which has a monolithic integration of a resistance, a capacitance and a Group III-V compound semiconductor hetero-junction bipolar transistor

2. Description of the Related Art

As mobile phones and optical communication systems have become widely spread, developments for high frequency and high output devices with reduced noise have become important. A hetero-junction bipolar transistor of a Group III-V compound semiconductor exhibits a superior high frequency performance and a high current driving capability and is operable by a single positive power source. The hetero-junction bipolar transistor is highly attractive. For applying the transistor to the mobile phone, it is necessary to reduce the chip size. In this viewpoint, it is important to develop such a monolithic microwave integrated circuit. In the past, after the hetero-junction bipolar transistor is formed as an active element, passive elements, for example, resistance and capacitance are formed separately from the transistor.

Japanese laid-open patent publication No 10-107042 discloses a conventional monolithic microwave integrated circuit. Such a conventional integrated circuit has the following problems. The hetero-junction bipolar transistor and the metal insulator metal capacitor are separately formed using separate sets of masks. This means that the total number of the necessary masks and fabrication processes are large. Different three metals are used for emitter, base and collector of the hetero-junction bipolar transistor. This makes the fabrication processes complicated. It is desired to avoid any further increase in the number of the fabrication processes.

The resistance is made of a resistive metal such as NiCr or WSiN. The resistive metal film is deposited by an evaporation process or a sputtering process, and then a patterning process is carried out to form a metal resistance. This increases the number of the fabrication processes. Alternatively, the resistance may comprise an epitaxial layer. A resistance value depends on the shape of the resistance, for which reason it is difficult to accurately control the resistance value. Further, if another epitaxial base layer underlies the above epitaxial layer, this epitaxial base layer generates a parasitic capacitance, which causes a frequency-dependency of the resistance value.

In the above circumstances, it had been required to develop a novel monolithic microwave integrated circuit free from the above problem.

### SUMMARY OF THE INVENTION

Accordingly, it is an object of the present invention to provide a novel monolithic microwave integrated circuit free from the above problems.

It is a further object of the present invention to provide a novel monolithic microwave integrated circuit having improved high frequency performances.

It is a still further object of the present invention to provide a novel monolithic microwave integrated circuit having suitable structure for simplification of the fabrication processes.

It is a still further object of the present invention to provide a novel monolithic microwave integrated circuit having a hetero-junction bipolar transistor with a reduced parasitic capacitance.

It is yet a further object of the present invention to provide a novel method of forming a monolithic microwave integrated circuit.

A primary aspect of the present invention is a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer, wherein the electrode contact layer and the resistive layer comprise the same compound semiconductor layer, and the electrode contact layer and the resistive layer are concurrently formed in the same processes. This reduces the number of the fabrication processes and the manufacturing cost.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a fragmentary cross sectional elevation view of a monolithic microwave integrated circuit in a first embodiment in accordance with the present invention.

FIG. 2 is a fragmentary cross sectional elevation view of a hetero-junction bipolar transistor in the monolithic microwave integrated circuit of FIG. 1.

FIGS. 3A through 3F are fragmentary cross sectional elevation views of monolithic microwave integrated circuits in sequential steps involved in a novel fabrication method in a first embodiment in accordance with the present invention.

FIG. 4 is a fragmentary cross sectional elevation view of a monolithic microwave integrated circuit in a second embodiment in accordance with the present invention.

FIG. 5 is a fragmentary cross sectional elevation view of a hetero-junction bipolar transistor in the monolithic microwave integrated circuit of FIG. 4.

FIGS. 6A through 6F are fragmentary cross sectional elevation views of monolithic microwave integrated circuits in sequential steps involved in a novel fabrication method in a second embodiment in accordance with the present invention.

### DETAILED DESCRIPTION

A first aspect of the present invention is a monolithically integrated semiconductor device comprising: a hetero-junction bipolar transistor having at least an electrode contact layer which contacts directly with at least one of collector, base and emitter electrodes and at least a passive device having at least a passive device electrode and at least a resistive layer, wherein the electrode contact layer and the resistive layer comprise the same compound semiconductor layer The electrode contact layer and the resistive layer are concurrently formed in the same processes. This reduces the number of the fabrication processes and the manufacturing cost.

It is possible that the passive device, electrode and one of the collector, base and emitter electrodes comprises the same metal layer. The passive device electrode and one of the collector, base and emitter electrodes are concurrently formed in the same processes. This reduces the number of the fabrication processes and the manufacturing cost.

It is also possible that the at least passive device further comprises: a resistive element which comprises: at least a resistive element layer; and at least a resistive element electrode; and a metal-insulator-metal capacitor which comprises a bottom electrode; a capacitive dielectric layer; and a top electrode. It is further possible that the at least electrode contact layer comprises a base electrode contact layer which contacts directly with the base electrode. It is further more possible that the base electrode contact layer, the resistive element layer and the capacitive dielectric layer comprise the same compound semiconductor layer. The base electrode contact layer, the resistive element layer and the capacitive dielectric layer are concurrently formed in the same processes. This reduces the number of the fabrication processes and the manufacturing cost.

It is moreover possible that the base electrode and the bottom electrode comprise the same metal layer. The base electrode and the bottom electrode are concurrently formed in the same processes. This reduces the number of the fabrication processes and the manufacturing cost.

It is also possible that the base electrode and the top electrode comprise the same metal layer. The base electrode and the top electrode are concurrently formed in the same processes. This reduces the number of the fabrication processes and the manufacturing cost.

It is also possible that the base electrode and the resistive element electrodes comprise the same metal layer. The base electrode and the resistive element electrodes are concurrently formed in the same processes. This reduces the number of the fabrication processes and the manufacturing cost.

It is possible that the at least electrode contact layer comprises a collector electrode contact layer which contacts directly with the collector electrode. It is further possible that the collector electrode contact layer, the resistive element layer and the capacitive dielectric layer comprise the same compound semiconductor layer. The collector electrode contact layer, the resistive element layer and the capacitive dielectric layer are concurrently formed in the same processes. This reduces the number of the fabrication processes and the manufacturing cost.

It is further more possible that the collector electrode and the bottom electrode comprise the same metal layer. The collector electrode and the bottom electrode are concurrently formed in the same processes. This reduces the number of the fabrication processes and the manufacturing cost.

It is possible that the collector electrode and the top electrode comprise the same metal layer. The collector electrode and the top electrode are concurrently formed in the same processes. This reduces the number of the fabrication processes and the manufacturing cost.

It is also possible that the collector electrode and the resistive element electrodes comprise the same metal layer. The collector electrode and the resistive element electrodes are concurrently formed in the same processes, This reduces the number of the fabrication processes and the manufacturing cost.

It is also possible that the at least electrode contact layer comprises an emitter electrode contact layer which contacts directly with the emitter electrode It is further more possible that the emitter electrode contact layer, the resistive element layer and the capacitive dielectric layer comprise the same compound semiconductor layer, The emitter electrode contact layer, the resistive element layer and the capacitive dielectric layer are concurrently formed in the same processes. This reduces the number of the fabrication processes and the manufacturing cost.

It is further more possible that the emitter electrode and the bottom electrode comprise the same metal layer. The emitter electrode and the bottom electrode are concurrently formed in the same processes. This reduces the number of the fabrication processes and the manufacturing cost.

It is also possible that the emitter electrode and the top electrode comprise the same metal layer, The emitter electrode and the top electrode are concurrently formed in the same processes. This reduces the number of the fabrication processes and the manufacturing cost.

It is also possible that the emitter electrode and the resistive element electrodes comprise the same metal layer. The emitter electrode and the resistive element electrodes are concurrently formed in the same processes. This reduces the number of the fabrication processes and the manufacturing cost.

It is also possible that the at least passive device further comprises: a resistive element which comprises: at least a resistive element layer; and at least a resistive element electrode. It is further more possible that the at least electrode contact layer comprises a base electrode contact layer which contacts directly with the base electrode. It is moreover possible that the base electrode contact layer and the resistive element layer comprise the same compound semiconductor layer. The base electrode contact layer and the resistive element layer are concurrently formed in the same processes. This reduces the number of the fabrication processes and the manufacturing cost.

It is still more possible that the base electrode and the resistive element electrodes comprise the same metal layer. The base electrode and the resistive element electrodes are concurrently formed in the same processes. This reduces the number of the fabrication processes and the manufacturing cost.

It is also possible that the at least electrode contact layer comprises a collector electrode contact layer which contacts directly with the collector electrode. It is further possible that the collector electrode contact layer and the resistive element layer comprise the same compound semiconductor layer. The collector electrode contact layer and the resistive element layer are concurrently formed in the same processes, This reduces the number of the fabrication processes and the manufacturing cost.

It is further more possible that the collector electrode and the resistive element electrodes comprise the same metal layer. The collector electrode and the resistive element electrodes are concurrently formed in the same processes. This reduces the number of the fabrication processes and the manufacturing cost.

It is also possible that the at least electrode contact layer comprises an emitter electrode contact layer which contacts directly with the emitter electrode. It is further more possible that the emitter electrode contact layer and the resistive element layer comprise the same compound semiconductor layer. The emitter electrode contact layer and the resistive element layer are concurrently formed in the same processes. This reduces the number of the fabrication processes and the manufacturing cost.

It is also possible that the emitter electrode and the resistive element electrodes comprise the same metal layer. The emitter electrode and the resistive element electrodes are concurrently formed in the same processes. This reduces the number of the fabrication processes and the manufacturing cost.

It is also possible that the at least passive device further comprises: a metal-insulator-metal capacitor which comprises: a bottom electrode; a capacitive dielectric layer; and a top electrode.

It is also possible that the at least electrode contact layer comprises a base electrode contact layer which contacts directly with the base electrode. It is further possible that the base electrode contact layer and the capacitive dielectric layer comprise the same compound semiconductor layer.

It is moreover possible that the base electrode and the bottom electrode comprise the same metal layer. The base electrode and the bottom electrode are concurrently formed in the same processes. This reduces the number of the fabrication processes and the manufacturing cost.

It is also possible that the base electrode and the top electrode comprise the same metal layer. The base electrode and the top electrode are concurrently formed in the same processes. This reduces the number of the fabrication processes and the manufacturing cost.

It is also possible that the at least electrode contact layer comprises a collector electrode contact layer which contacts directly with the collector electrode. It is further more possible that the collector electrode contact layer and the capacitive dielectric layer comprise the same compound semiconductor layer The collector electrode contact layer and the capacitive dielectric layer are concurrently formed in the same processes. This reduces the number of the fabrication processes and the manufacturing cost.

It is still more possible that the collector electrode and the bottom electrode comprise the same metal layer. The collector electrode and the bottom electrode are concurrently formed in the same processes. This reduces the number of the fabrication processes and the manufacturing cost.

It is also possible that the collector electrode and the top electrode comprise the same metal layer. The collector electrode and the top electrode are concurrently formed in the same processes. This reduces the number of the fabrication processes and the manufacturing cost.

It is also possible that the at least electrode contact layer comprises an emitter electrode contact layer which contacts directly with the emitter electrode. It is further possible that the emitter electrode contact layer and the capacitive dielectric layer comprise the same compound semiconductor layer. The emitter electrode contact layer and the capacitive dielectric layer are concurrently formed in the same processes. This reduces the number of the fabrication processes and the manufacturing cost.

It is further more possible that the emitter electrode and the bottom electrode comprise the same metal layer. The emitter electrode and the bottom electrode are concurrently formed in the same processes. This reduces the number of the fabrication processes and the manufacturing cost.

It is also possible that the emitter electrode and the top electrode comprise the same metal layer. The emitter electrode and the top electrode are concurrently formed in the same processes. This reduces the number of the fabrication processes and the manufacturing cost.

A second aspect of the present invention is a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer, wherein the passive device electrode and one of the collector, base and emitter electrodes comprises the same metal layer.

This second aspect of the present invention has the same characteristics described above in connection with the first aspect of the present invention.

It is also possible that the electrode contact layer and the resistive layer comprise the same compound semiconductor layer. It is further possible that the at least passive device further comprises: a resistive element which comprises: at least a resistive element layer; and at least a resistive element electrode; and a metal-insulator-metal capacitor which comprises: a bottom electrode; a capacitive dielectric layer; and a top electrode.

It is also possible that the at least passive device further comprises: a resistive element which comprises: at least a resistive element layer; and at least a resistive element electrode.

It is also possible that the at least passive device further comprises: a metal-insulator-metal capacitor which comprises: a bottom electrode; a capacitive dielectric layer; and a top electrode.

A third aspect of the present invention is a monolithically integrated semiconductor device comprising: a hetero-junction bipolar transistor having at least an electrode contact layer which contacts directly with at least one of collector, base and emitter electrodes; a resistive element which comprises: at least a resistive element layer; and at least a resistive element electrode; and a metal-insulator-metal capacitor which comprises: a bottom electrode; a capacitive dielectric layer; and a top electrode, wherein the electrode contact layer, the resistive element layer and the capacitive dielectric layer comprise the same compound semiconductor layer, and wherein the resistive element electrode, the top electrode and the at least one of collector, base and emitter electrodes comprises the same metal layer.

This third aspect of the present invention has the same characteristics described above in connection with the first aspect of the present invention.

A fourth aspect of the present invention is a method of forming a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer, wherein the electrode contact layer and the resistive layer are formed concurrently in the same processes.

This fourth aspect of the present invention has the same characteristics described above in connection with the first aspect of the present invention.

It is also possible that the passive device electrode and one of the collector, base and emitter electrodes are formed concurrently in the same processes.

This fourth aspect of the present invention has the same characteristics described above in connection with the first aspect of the present invention.

A fifth aspect of the present invention is a method of forming a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer, wherein the passive device electrode and one of the collector, base and emitter electrodes are formed concurrently in the same processes.

This fifth aspect of the present invention has the same characteristics described above in connection with the first aspect of the present invention.

It is also possible that the electrode contact layer and the resistive layer are formed concurrently in the same processes.

A sixth aspect of the present invention is a monolithically integrated semiconductor device comprising: a hetero-junction bipolar transistor having at least an electrode contact layer which contacts directly with at least one of collector, base and emitter electrodes; a resistive element which comprises: at least a resistive element layer; and at least a resistive element electrode; and a metal-insulator-metal capacitor which comprises: a bottom electrode; a capacitive dielectric layer; and a top electrode, wherein the electrode contact layer, the resistive element layer and the capacitive dielectric layer are formed concurrently in the same processes, and wherein the resistive element electrode, the top electrode and the at least one of collector, base and emitter electrodes are formed concurrently in the same processes.

This sixth aspect of the present invention has the same characteristics described above in connection with the first aspect of the present invention.

### PREFERRED EMBODIMENTS

### First Embodiment

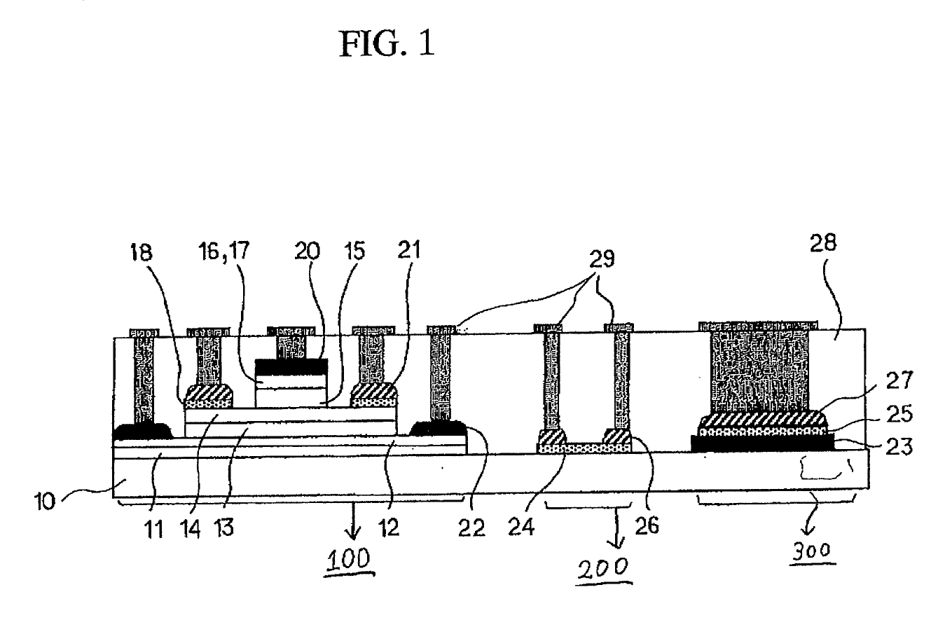

A first embodiment according to the present invention will be described in detail with reference to the drawings. FIG. 1 is a fragmentary cross sectional elevation view of a monolithic microwave integrated circuit in a first embodiment in accordance with the present invention. A monolithic microwave integrated circuit is provided on a semi-insulating GaAs substrate 10. The monolithic microwave integrated circuit has a monolithic integration of a hetero-junction bipolar transistor 100, a restive element 200 and a metal-insulator-metal capacitor 300.

The hetero-unction bipolar transistor 100 has an emitter electrode 20, a base electrode 21, and a collector electrode 22. The restive element 200 has a p+-GaAs resistive layer 24 and resistive element electrodes 26. The metal-insulating-metal capacitor 300 has a bottom electrode 23, a p+-GaAs polycrystalline layer 25, and a top electrode 27, wherein the p+-GaAs polycrystalline layer 25 is sandwiched between the top and bottom electrodes 27 and 23, so that the p+-GaAs polycrystalline layer 25 serves as a dielectric, which is a medium capable of maintaining an electric field with no supply of energy from outside source.

An inter-layer insulator 28 of silicon dioxide entirely overlies the substrate, so that the hetero-junction bipolar transistor 100, the restive element 200 and the metal-insulator-metal capacitor 300 are buried in the inter-layer insulator 28. The emitter electrode 20, the base electrode 21, and the collector electrode 22, and the resistive element electrodes 26 as well as the top electrode 27 are electrically connected through contact electrode contacts to second level interconnections 29. The contact electrode contacts are provided in contact holes formed in the inter-layer insulator 28. The second level interconnections 29 extend over the inter-layer insulator 28. The inter-layer insulator 28 has a planarized top surface.

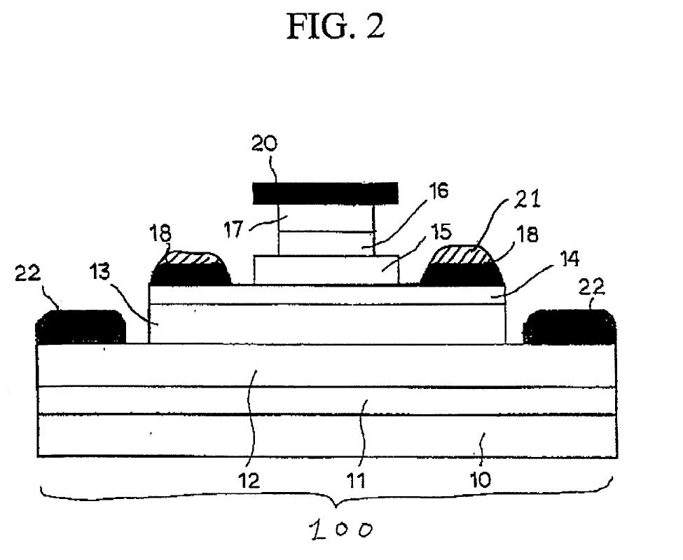

FIG. 2 is a fragmentary cross sectional elevation view of a hetero-junction bipolar transistor in the monolithic microwave integrated circuit of FIG. 1. A buffer layer 11 overlies a top surface of the semi-insulating GaAs substrate 10. The buffer layer 11 may have a thickness of 500 nanometers. The buffer layer 11 may comprise either an i-GaAs or an i-AlGaAs. “i-GaAs” or “i-AlGaAs” means “intrinsic GaAs” and “intrinsic AlGaAs”. An n+-GaAs sub-collector layer 12 overlies the buffer layer 11. The n+-GaAs sub-collector layer 12 may have an Si-doping concentration of at least 1×10¹⁸ cm⁻³. The n+-GaAs sub-collector layer 12 may have a thickness of 500 nanometers. An n-GaAs collector layer 13 selectively overlies a predetermined region of a top surface of the n+-GaAs sub-collector layer 12. The n-GaAs collector layer 13 may have an Si-doping concentration of at least 5×10¹⁶ cm⁻³. The n-GaAs collector layer 13 may have a thickness of 500 nanometers.

A p+-GaAs base layer 14 overlies the n-GaAs collector layer 13. The p+-GaAs base layer 14 may have a C-doping concentration of at least 3×10¹⁹ cm⁻³. The p+-GaAs base layer 14 may have a thickness of 80 nanometers. An emitter layer 15 selectively overlies a predetermined region of a top surface of the p+-GaAs base layer 14. The emitter layer 15 may comprise either n-AlGaAs doped with Si at 3×10¹⁷ cm⁻³ or n-InGaAs doped with Si at 3×10¹⁷ cm⁻³. The emitter layer 15 may have a thickness of 100 nanometers. A first emitter cap layer 16 selectively overlies a predetermined region of a top surface of the emitter layer 15. The first emitter cap layer 16 may comprise n+-GaAs doped with Si at 1×10¹⁸ cm⁻³. The first emitter cap layer 16 may have a thickness of 100 nanometers. A second emitter cap layer 17 overlies the first emitter cap layer 16. The second emitter cap layer 17 may comprise n+-InGaAs doped with Si at 1×10¹⁸ cm⁻³. The second emitter cap layer 17 may have a thickness of 100 nanometers.

Base electrode contact layers 18 are selectively provided on other selected regions of the top surface of the p+-GaPs base layer 14, so that the base electrode contact layers 18 are separated from the emitter layer 15. The base electrode contact layers 18 may comprise p+GaAs doped with C at 1×10²⁰ cm⁻³. The base electrode contact layers 18 may have a thickness of 100 nanometers. Base electrodes 21 are provided on the base electrode contact layers 18. The base electrodes 21 may comprise laminations of a Ti-layer, a Pt-layer and an Au-layer. An emitter electrode 20 is provided on a top surface of the second emitter cap layer 17. The emitter electrode 20 may comprise tungsten silicide. Collector electrodes 22 are provided on other selected regions of the top surface of the n+-GaAs sub-collector layer 12, so that the collector electrodes 22 are separated from the n-GaAs collector layer 13. The collector electrodes 22 may comprise either first laminations of a Ni-layer, an AuGe-layer and an Au-layer or second laminations of a Ti-layer, a Pt-layer and an Au-layer.

The collector electrodes 22 of the hetero-junction bipolar transistor 100 and the bottom electrode 23 of the metal-insulating-metal capacitor 300 comprise the same metal layer and are concurrently formed in the same process. This metal layer may comprise either the first laminations of a Ni-layer; an AuGe-layer and an Au-layer or second laminations of a Ti-layer, a Pt-layer and an Au-layer.

Further, the base electrode contact layers 18 of the hetero-junction bipolar transistor 100, the resistive layer 24 of the resistive element 200 and the dielectric polycrystalline layer 25 of the metal-insulating-metal capacitor 300 comprise the same p+-GaAs layer and are concurrently formed in the same process.

Furthermore, the base electrodes 21 of the hetero-junction bipolar transistor 100, the resistive clement electrodes 26 of the resistive clement 200 and the top electrode 27 of the metal-insulating-metal capacitor 300 comprise the same metal layer and are concurrently formed in the same process.

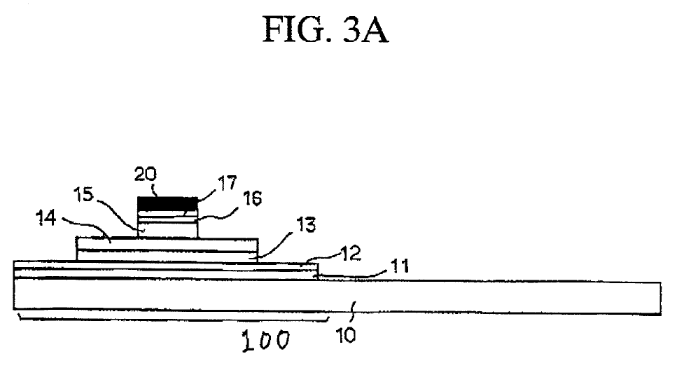

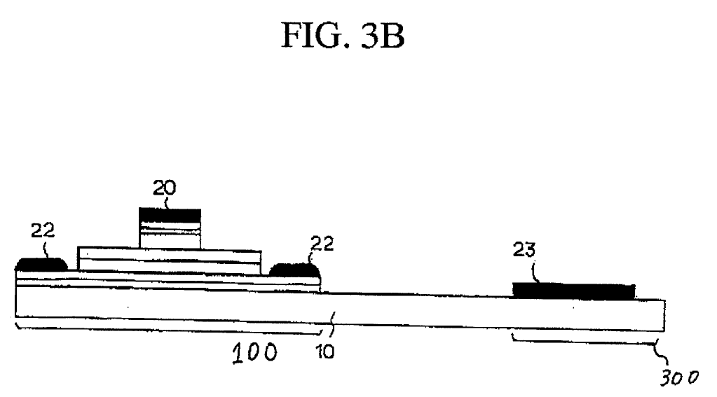

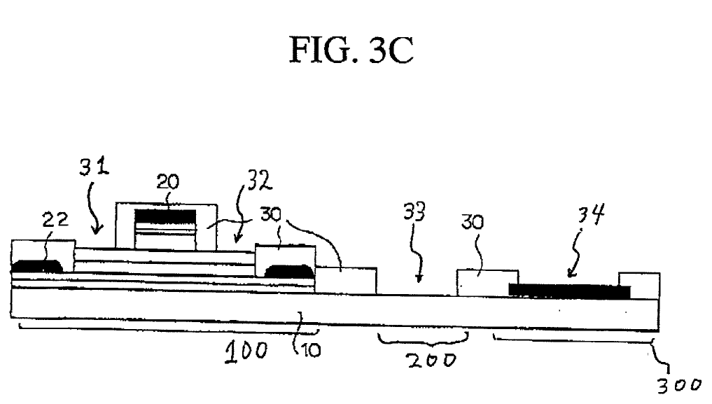

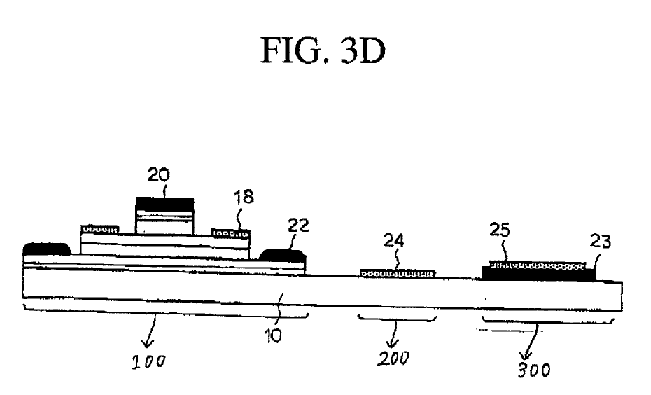

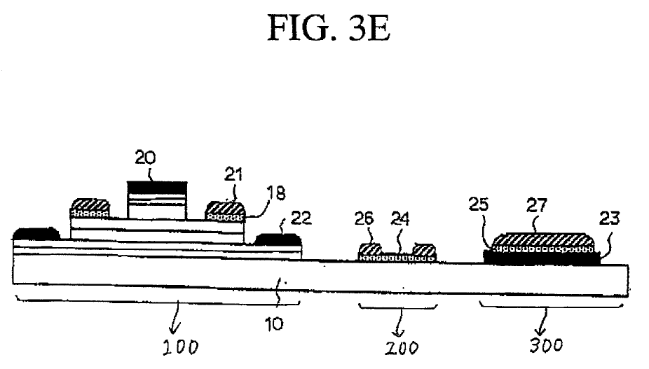

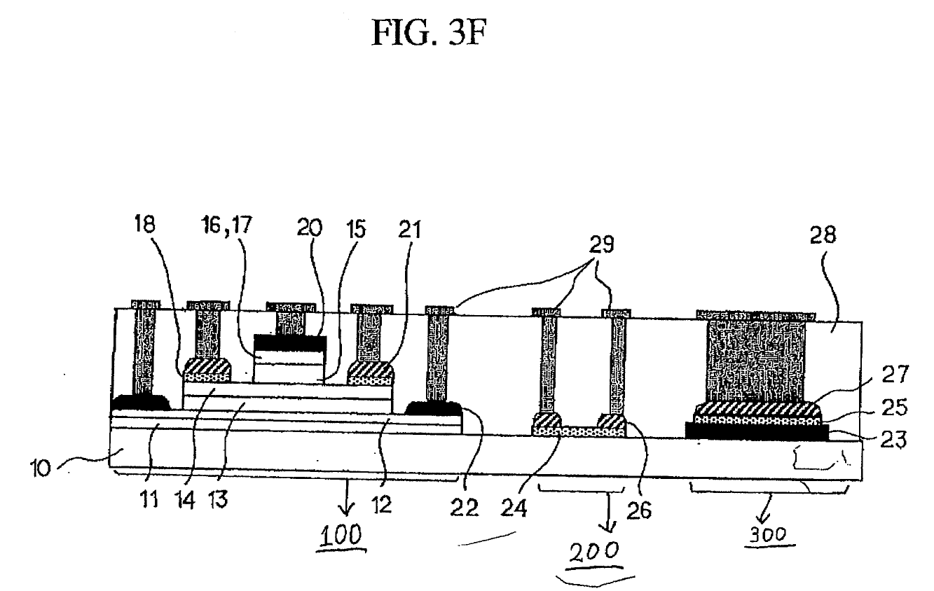

FIGS. 3A through 3F are fragmentary cross sectional elevation views of monolithic microwave integrated circuits in sequential steps involved in a novel fabrication method in a first embodiment in accordance with the present invention.

With reference to FIG. 3A, the buffer layer 11 is entirely formed on a top surface of the semi-insulating GaAs substrate 10 by a metal organic vapor phase epitaxy. The n+-GaAs sub-collector layer 12 is entirely formed on a top surface of the buffer layer 11 by a metal organic vapor phase epitaxy. The n-GaAs collector layer 13 is entirely formed on a top surface of the n+-GaAs sub-collector layer 12 by a metal organic vapor phase epitaxy. The p+-GaAs base layer 14 is entirely formed on a top surface of the n-GaAs collector layer 13 by a metal organic vapor phase epitaxy. The emitter layer 15 is entirely formed on a top surface of the p+-GaAs base layer 14 by a metal organic vapor phase epitaxy. A first emitter cap layer 16 is entirely formed on a top surface of the emitter layer 15 by a metal organic vapor phase epitaxy. The second emitter cap layer 17 is entirely formed on a top surface of the first emitter cap layer 16 by a metal organic vapor phase epitaxy.

A tungsten silicide layer is entirely deposited on a top surface of the second emitter cap layer 17 by a sputtering process. A photo-resist film is applied on the tungsten silicide layer. The photo-resist film is patterned by photo-lithography processes to form a photo-resist mask. A dry etching process is carried out using the photo-resist mask for selectively etching the tungsten silicide layer, thereby selectively forming the emitter electrode 20 on a predetermined region of the top surface of the second emitter cap layer 17. A wet etching process is carried out for selectively and isotropically etching the second and first emitter cap layers 17 and 16 and the emitter layer 15, whereby the top surface of the base layer 14 is exposed, except under the remaining emitter layer 15.

Further, another photo-resist mask is selectively formed over the exposed top surface of the base layer 14. A wet etching process is carried out for selectively and isotropically etching the base layer 14 and the collector layer 13, whereby the top surface of the sub-collector layer 12 is exposed, except under the remaining collector layer 13.

Furthermore, still another photo-resist mask is selectively formed over the exposed top surface of the sub-collector layer 12. An etching process is carried out for selectively etching the sub-collector layer 12 and the buffer layer 11, whereby the top surface of the substrate 10 is exposed, except on the hetero-junction bipolar transistor region 100. The used photo-resist mask is removed.

With reference to FIG. 3B, a metal layer is selectively formed by a lift-off method, whereby the collector electrodes 22 and the bottom electrode 23 are concurrently formed. The collector electrodes 22 and the bottom electrode 23 comprise the same metal layer. This metal layer may comprise either the first laminations of a Ni-layer, an AuGe-layer and an Au-layer or second laminations of a Ti-layer, a Pt-layer and an Au-layer. Optionally, it is possible to concurrently form first level interconnections which comprise the same metal layer as the collector electrodes 22 and the bottom electrode 23, even the first level interconnections are not illustrated in the drawings.

With reference to FIG. 3C, a silicon dioxide film 30 having a thickness of 100 nanometers is entirely deposited over the substrate. A resist mask is selectively formed on the silicon dioxide film 30. A selective wet etching process is carried out using the resist mask for selectively etching the silicon dioxide film 30. First and second openings 31 and 32 are selectively formed in the silicon dioxide film 30 over the hetero-junction bipolar transistor region 100. A third opening 33 is selectively formed in the silicon dioxide film 30 over the resistive element region 200. A fourth opening 34 is selectively formed in the silicon dioxide film 30 over the metal-insulating-metal capacitor region 300. The resist mask is then removed.

With reference to FIG. 3D, a metal organic molecular beam epitaxy method is carried out using the silicon dioxide film 30 as a mask for selectively forming p+-GaAs layers in the first to fourth openings 31, 32, 33 and 34. The p+-GaAs layers may have a doping concentration of 1×10²⁰ cm⁻³. The p+-GaAs layers may have a thickness of 100 nanometers. In the first and second openings 31 and 32, the p+-GaAs layers form the base electrode contact layers 18. In the third opening 33, the p+-GaAs layer forms the resistive layer 24. In the fourth opening 34, the p+-GaAs layer forms the dielectric polycrystalline layer 25. The used silicon dioxide layer 30 is removed.

The size of the resistive layer 24 is defined by the size of the third opening 33. A sheet resistance of the resistive layer 24 depends on the size of the resistive layer 24. The size of the third opening 33 is decided so that the sheet resistance of the resistive layer 24 is about 120 ohms.

In the fourth opening 34, the p+-GaAs layer is grown in polycrytstal on the metal bottom electrode 23. A polycrystal Group III-V compound semiconductor has a high resistivity, for which reason the polyerystalline p+-GaAs layer 25 serves as a dielectric layer of the capacitor 300.

Namely, the base electrode contact layers IS of the hetero-junction bipolar transistor 100, the resistive layer 24 of the resistive element 200 and the dielectric polycrystalline layer 25 of the metal-insulating-metal capacitor 300 comprise the same p+-GaAs layer and are concurrently formed in the single process.

With reference to FIG. 3E, a metal layer is selectively formed by a lift-off method, whereby the base electrodes 21, the resistive element electrodes 26 and the top electrode 27 are concurrently formed. The base electrodes 21, the resistive element electrodes 26 and the top electrode 27 comprise the same metal layer. This metal layer may comprise the laminations of a Ti-layer, a Pt-layer and an Au-layer.

With reference to FIG. 3F, an inter-layer insulator 28 of silicon dioxide is entirely formed over the substrate 10, so that the hetero-junction bipolar transistor 100, the resistive element 200 and the metal-insulator-metal capacitor 300 are completely buried in the inter-layer insulator 28. A top surface of the inter-layer insulator 28 is planarized. Contact holes are formed in the inter-layer insulator 28, so that the contact holes reach the emitter electrode 20, the base electrodes 21, the collector electrodes 22, the resistive element electrodes 26 and the top electrode 27.

Contact electrode contacts are formed in the contact holes, wherein the contact electrode contacts are in contact with the emitter electrode 20, the base electrodes 21, the collector electrodes 22, the resistive element electrodes 26 and the top electrode 27. Second level interconnections 29 are formed over the planarized top surface of the inter-layer insulator 28, so that the second level interconnections 29 are connected through the contact electrode contacts to the emitter electrode 20, the base electrodes 21, the collector electrodes 22, the resistive element electrodes 26 and the top electrode 27. The monolithic microwave integrated circuit is fabricated.

As described above, the collector electrodes 22 of the hetero-junction bipolar transistor 100 and the bottom electrode 23 of the metal-insulating-metal capacitor 300 comprise the same metal layer and are concurrently formed in the same process. Further, the base electrode contact layers 18 of the hetero-junction bipolar transistor 100, the resistive layer 24 of the resistive element 200 and the dielectric polycrystalline layer 25 of the metal-insulating-metal capacitor 300 comprise the same p+-GaAs layer and are concurrently formed in the same process. Furthermore, the base electrodes 21 of the hetero-junction bipolar transistor 100, the resistive element electrodes 26 of the resistive element 200 and the top electrode 27 of the metal-insulating-metal capacitor 300 comprise the same metal layer and are concurrently formed in the same process. Those reduce the number of the fabrication processes.

The resistance value of the resistive element 200 is accurately controllable by controlling the size of the third opening in the silicon dioxide mask.

The base electrodes 21 overly the p+-GaAs base electrode contact layers 18 with a reduced contact resistance, which reduces a parasitic capacitance. The reduced parasitic capacitance improves high frequency performance of the hetero-junction bipolar transistor.

It is possible as a modification to change the compound of the semiconductors. The monolithic microwave integrated circuit is formed over an InP substrate 10. The hetero-junction bipolar transistor 100 has the emitter electrode 20, the base electrode 21, and the collector electrode 22. The restive element 200 has a p+-InGaAs resistive layer 24 and resistive element electrodes 26. The metal-insulating-metal capacitor 300 has a bottom electrode 23, a p+-InGaAs polycrystalline layer 25, and a top electrode 27, wherein the p+-InGaAs polycrystalline layer 25 is sandwiched between the top and bottom electrodes 27 and 23, so that the p+-InGaAs polycrystalline layer 25 serves as a dielectric, which is a medium capable of maintaining an electric field with no supply of energy from outside source.

An inter-layer insulator 28 of silicon dioxide entirely overlies the substrate, so that the hetero-junction bipolar transistor 100, the restive element 200 and the metal-insulator-metal capacitor 300 are buried in the inter-layer insulator 28. The emitter electrode 20, the base electrode 21, and the collector electrode 22, and the resistive element electrodes 26 as well as the top electrode 27 are electrically connected through contact electrode contacts to second level interconnections 29. The contact electrode contacts are provided in contact holes formed in the inter-layer insulator 28. The second level interconnections 29 extend over the inter-layer insulator 28. The inter-layer insulator 28 has a planarized top surface.

A buffer layer 11 overlies a top surface of the semi-insulating GaAs substrate 10. The buffer layer 11 may have a thickness of 500 nanometers. The buffer layer 11 may comprise an i-InP. An n+-InGaAs sub-collector layer 12 overlies the buffer layer 11. The n+-InGaAs sub-collector layer 12 may have an Si-doping concentration of at least 1×10¹⁸ cm⁻³. The n+-GaAs sub-collector layer 12 may have a thickness of 500 nanometers. An n-InGaAs collector layer 13 selectively overlies a predetermined region of a top surface of the n+-InGaAs sub-collector layer 12. The n-InGaAs collector layer 13 may have an Si-doping concentration of at least 5×10¹⁶ cm⁻³. The n-InGaAs collector layer 13 may have a thickness of 500 nanometers.

A p+-InGaAs base layer 14 overlies the n-InGaAs collector layer 13. The p+-InGaAs base layer 14 may have a C-doping concentration of at least 3×10¹⁹ cm⁻³. The p+-GaAs base layer 14 may have a thickness of 80 nanometers. An emitter layer 15 selectively overlies a predetermined region of a top surface of the p+-InGaAs base layer 14. The emitter layer 15 may comprise either n-InAlAs doped with Si at 3×10¹⁷ cm⁻³ or n-InP doped with Si at 3×10¹⁷ cm⁻³. The emitter layer 15 may have a thickness of 100 nanometers. A first emitter cap layer 16 selectively overlies a predetermined region of a top surface of the emitter layer 15. The first emitter cap layer 16 may comprise n+-InGaAs doped with Si at 1×10¹⁸ cm⁻³. The first emitter cap layer 16 may have a thickness of 100 nanometers. A second emitter cap layer 17 overlies the first emitter cap layer 16. The second emitter cap layer 17 may comprise n+-InGaAs doped with Si at 1×10¹⁸ cm⁻³. The second emitter cap layer 17 may have a thickness of 100 nanometers.

Base electrode contact layers 18 are selectively provided on other selected regions of the top surface of the p+-InGaAs base layer 14, so that the base electrode contact layers 18 are separated from the emitter layer 15. The base electrode contact layers 18 may comprise p+-InGaAs doped with C at 1×10²⁰ cm⁻³. The base electrode contact layers 18 may have a thickness of 100 nanometers. Base electrodes 21 are provided on the base electrode contact layers 18. The base electrodes 21 may comprise laminations of a Ti-layer, a Pt-layer and an Au-layer. An emitter electrode 20 is provided on a top surface of the second emitter cap layer 17. The emitter electrode 20 may comprise tungsten silicide. Collector electrodes 22 are provided on other selected regions of the top surface of the n+-InGaAs sub-collector layer 12, so that the collector electrodes 22 are separated from the n-InGaAs collector layer 13. The collector electrodes 22 may comprise either first laminations of a Ni-layer, an AuGe-layer and an Au-layer or second laminations of a Ti-layer, a Pt-layer and an Au-layer.

The above modified monolithic microwave integrated circuit may be formed by the same fabrication processes as described with reference to FIGS. 3A through 3F.

The above modified monolithic microwave integrated circuit provides the same advantages as described with reference to FIG. 2. Namely, the collector electrodes 22 of the hetero-junction bipolar transistor 100 and the bottom electrode 23 of the metal-insulating-metal capacitor 300 comprise the same metal layer and are concurrently formed in the same process. This metal layer may comprise either the first laminations of a Ni-layer, an AuGe-layer and an Au-layer or second laminations of a Ti-layer, a Pt-layer and an Au-layer. Further, the base electrode contact layers 18 of the hetero-junction bipolar transistor 100, the resistive layer 24 of the resistive element 200 and the dielectric polycrystalline layer 25 of the metal-insulating-metal capacitor 300 comprise the same p+-InGaAs layer and are concurrently formed in the same process. Furthermore, the base electrodes 21 of the hetero-junction bipolar transistor 100, the resistive element electrodes 26 of the resistive element 200 and the top electrode 27 of the metal-insulating-metal capacitor 300 comprise the same metal layer and are concurrently formed in the same process. Those reduce the number of the fabrication processes.

The resistance value of the resistive element 200 is accurately controllable by controlling the size of the third opening in the silicon dioxide mask.

The base electrodes 21 overly the p+-GaAs base electrode contact layers 18 with a reduced contact resistance, which reduces a parasitic capacitance. The reduced parasitic capacitance improves high frequency performance of the hetero-junction bipolar transistor.

### Second Embodiment

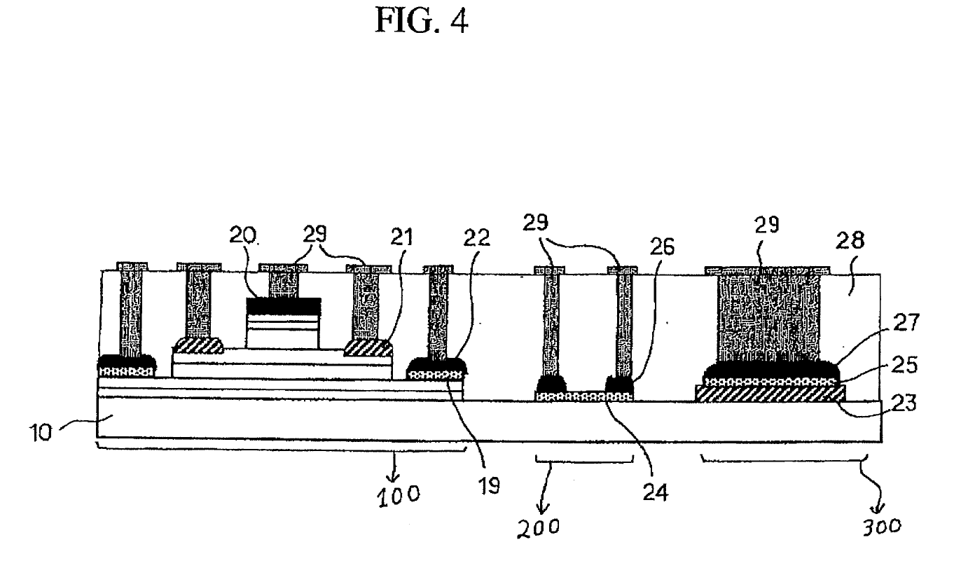

A second embodiment according to the present invention will be described in detail with reference to the drawings. FIG. 4 is a fragmentary cross sectional elevation view of a monolithic microwave integrated circuit in a second embodiment in accordance with the present invention. A monolithic microwave integrated circuit is provided on a semi-insulating GaAs substrate 10. The monolithic microwave integrated circuit has a monolithic integration of a hetero-junction bipolar transistor 100, a restive element 200 and a metal-insulator-metal capacitor 300.

The hetero-junction bipolar transistor 100 has an emitter electrode 20, a base electrode 21, and a collector electrode 22. The restive element 200 has a p+-GaAs resistive layer 24 and resistive element electrodes 26. The metal-insulating-metal capacitor 300 has a bottom electrode 23, a p+-GOas polycrystalline layer 25, and a top electrode 27, wherein the p+-GaAs polycrystalline layer 25 is sandwiched between the top and bottom electrodes 27 and 23, so that the p+-GaAs polycrystalline layer 25 serves as a dielectric, which is a medium capable of maintaining an electric field with no supply of energy from outside source.

An inter-layer insulator 28 of silicon dioxide entirely overlies the substrate, so that the hetero-junction bipolar transistor 100, the restive element 200 and the metal-insulator-metal capacitor 300 are buried in the inter-layer insulator 28. The emitter electrode 20, the base electrode 21, and the collector electrode 22, and the resistive element electrodes 26 as well as the top electrode 27 are electrically connected through contact electrode contacts to second level interconnections 29. The contact electrode contacts are provided in contact holes formed in the inter-layer insulator 28. The second level interconnections 29 extend over the inter-layer insulator 28. The inter-layer insulator 28 has a planarized top surface.

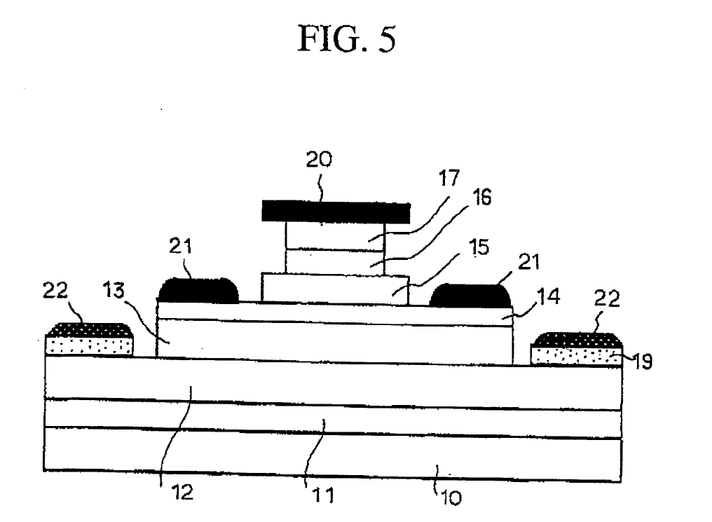

FIG. 5 is a fragmentary cross sectional elevation view of a hetero-junction bipolar transistor in the monolithic microwave integrated circuit of FIG. 4. A buffer layer 11 overlies a top surface of the semi-insulating GaAs substrate 10. The buffer layer 11 may have a thickness of 500 nanometers. The buffer layer 11 may comprise either an i-GaAs or an i-AlGaAs. “i-GaAs” or “i-AlGaAs” means “intrinsic GaAs” and “intrinsic AlGaAs”. An n+-GaAs sub-collector layer 12 overlies the buffer layer 11. The n+-GiaAs sub-collector layer 12 may have an Si-doping concentration of at least 1×10¹⁸ cm⁻³. The n+-GaAs sub-collector layer 12 may have a thickness of 500 nanometers. An n-GaAs collector layer 13 selectively overlies a predetermined region of a top surface of the n+-GaAs sub-collector layer 12. The n-GaAs collector layer 13 may have an Si-doping concentration of at least 5×10¹⁶ cm⁻³. The n-GaAs collector layer 13 may have a thickness of 500 nanometers.

A p+-GaAs base layer 14 overlies the n-GaAs collector layer 13. The p+-GaAs base layer 14 may have a C-doping concentration of at least 3×10¹⁹ cm⁻³. The p+-GaAs base layer 14 may have a thickness of 80 nanometers. An emitter layer 15 selectively overlies a predetermined region of a top surface of the p+GaAs base layer 14. The emitter layer 15 may comprise either n-AlGaAs doped with Si at 3×10¹⁷ cm⁻³ or n-InGaAs doped with Si at 3×10¹⁷ cm⁻³. The emitter layer 15 may have a thickness of 100 nanometers. A first emitter cap layer 16 selectively overlies a predetermined region of a top surface of the emitter layer 15. The first emitter cap layer 16 may comprise n+-GaAs doped with Si at 1×10¹⁸ cm⁻³. The first emitter cap layer 16 may have a thickness of 100 nanometers. A second emitter cap layer 17 overlies the first emitter cap layer 16. The second emitter cap layer 17 may comprise n+-InGaAs doped with Si at 1×10¹⁸ cm⁻³. The second emitter cap layer 17 may have a thickness of 100 nanometers.

Collector electrode contact layers 19 are selectively provided on other selected regions of the top surface of the n+-GaAs sub-collector layer 12, so that the collector electrode contact layers 19 are separated from the collector layer 13. The collector electrode contact layers 19 may comprise n+-GaAs doped with Si at 1×10¹⁹ cm⁻³. The collector electrode contact layers 19 may have a thickness of 100 nanometers. Collector electrodes 22 are provided on the collector layer 13, so that the collector electrodes 22 are separated from the n-GaAs collector layer 13. The collector electrodes 22 may comprise either first laminations of a Ni-layer, an AuGe-layer and an Au-layer or second laminations of a Ti-layer, a Pt-layer and an Au-layer. Base electrodes 21 are provided on the other regions of the top surface of the base layer 14. The base electrodes 21 may comprise laminations of a Ti-layer, a Pt-layer and an Au-layer. An emitter electrode 20 is provided on a top surface of the second emitter cap layer 17. The emitter electrode 20 may comprise tungsten silicide.

Namely, the base electrodes 21 of the hetero-junction bipolar transistor 100 and the bottom electrode 23 of the metal-insulating-metal capacitor 300 comprise the same metal layer and are concurrently formed in the same process. This metal layer may comprise either the first laminations of a Ni-layer, an AuGe-layer and an Au-layer or second laminations of a Ti-layer, a Pt-layer and an Au-layer.

Further, the collector electrode contact layers 19 of the hetero-junction bipolar transistor 100, the resistive layer 24 of the resistive element 200 and the dielectric polycrystalline layer 25 of the metal-insulating-metal capacitor 300 comprise the same n+-InGaAs layer and are concurrently formed in the same process.

Furthermore, the collector electrodes 22 of the hetero-junction bipolar transistor 100, the resistive element electrodes 26 of the resistive element 200 and the top electrode 27 of the metal-insulating-metal capacitor 300 comprise the same metal layer and are concurrently formed in the same process. Those reduce the number of the fabrication processes.

The resistance value of the resistive element 200 is accurately controllable by controlling the size of the third opening in the silicon dioxide mask.

The base electrodes 21 overly the p+-GaAs base electrode contact layers 18 with a reduced contact resistance, which reduces a parasitic capacitance. The reduced parasitic capacitance improves high frequency performance of the hetero-junction bipolar transistor.

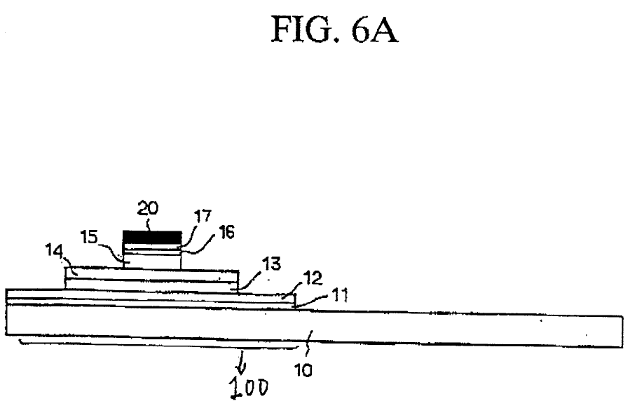

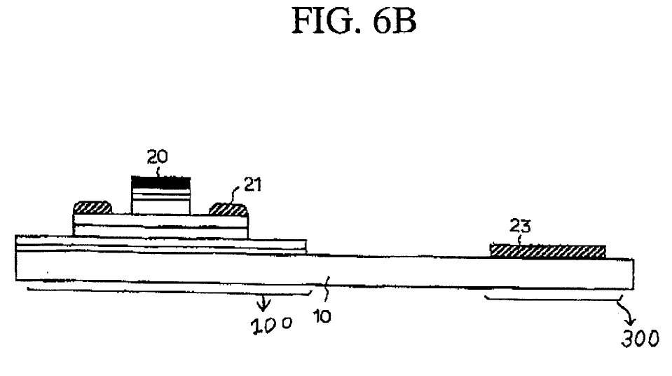

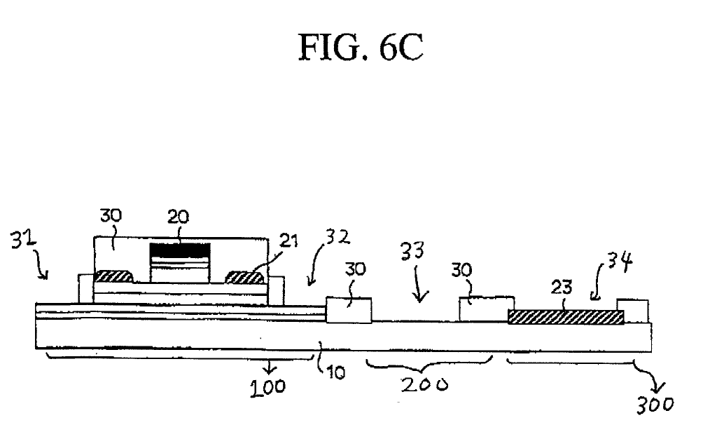

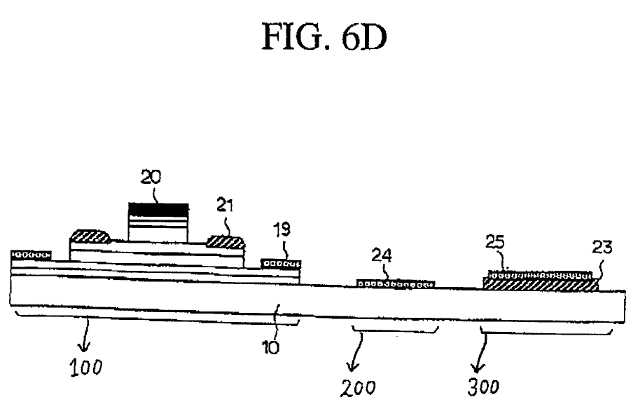

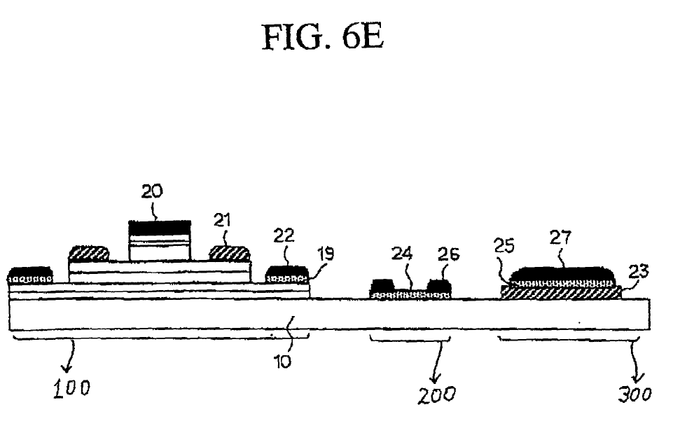

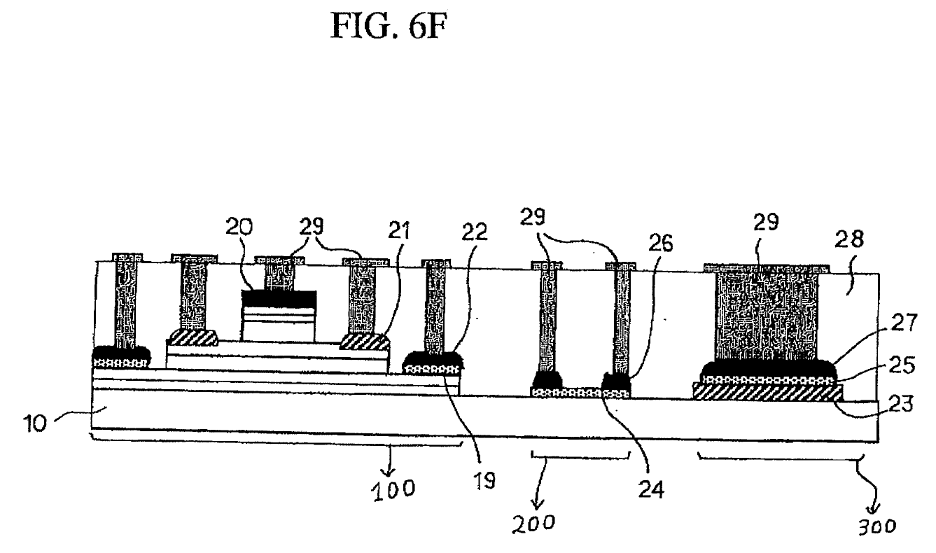

FIGS 6A through 6F are fragmentary cross sectional elevation views of monolithic microwave integrated circuits in sequential steps involved in a novel fabrication method in a second embodiment in accordance with the present invention.

With reference to FIG. 6A, the buffer layer 11 is entirely formed on a top surface of the semi-insulating GaAs substrate 10 by a metal organic vapor phase epitaxy. The n+-GaAs sub-collector layer 12 is entirely formed on a top surface of the buffer layer 11 by a metal organic vapor phase epitaxy. The n-GaAs collector layer 13 is entirely formed on a top surface of the n+-GaAs sub-collector layer 12 by a metal organic vapor phase epitaxy. The p+-GaAs base layer 14 is entirely formed on a top surface of the n-GaAs collector layer 13 by a metal organic vapor phase epitaxy. The emitter layer 15 is entirely formed on a top surface of the p+-GaAs base layer 14 by a metal organic vapor phase epitaxy. A first emitter cap layer 16 is entirely formed on a top surface of the emitter layer 15 by a metal organic vapor phase epitaxy. The second emitter cap layer 17 is entirely formed on a top surface of the first emitter cap layer 16 by a metal organic vapor phase epitaxy.

A tungsten silicide layer is entirely deposited on a top surface of the second emitter cap layer 17 by a sputtering process. A photo-resist film is applied on the tungsten silicide layer. The photo-resist film is patterned by photo-lithography processes to form a photo-resist mask. A dry etching process is carried out using the photo-resist mask for selectively etching the tungsten silicide layer, thereby selectively forming the emitter electrode 20 on a predetermined region of the top surface of the second emitter cap layer 17. A wet etching process is carried out for selectively and isotropically etching the second and first emitter cap layers 17 and 16 and the emitter layer 15, whereby the top surface of the base layer 14 is exposed, except under the remaining emitter layer 15.

Further, another photo-resist mask is selectively formed over the exposed top surface of the base layer 14. A wet etching process is carried out for selectively and isotropically etching the base layer 14 and the collector layer 13, whereby the top surface of the sub-collector layer 12 is exposed, except under the remaining collector layer 13.

Furthermore, still another photo-resist mask is selectively formed over the exposed top surface of the sub-collector layer 12. An etching process is carried out for selectively etching the sub-collector layer 12 and the buffer layer 11, whereby the top surface of the substrate 10 is exposed, except on the hetero-junction bipolar transistor region 100. The used photo-resist mask is removed.

With reference to FIG. 61B, a metal layer is selectively formed by a lift-off method, whereby the base electrodes 21 and the bottom electrode 23 are concurrently formed. The base electrodes 21 and the bottom electrode 23 comprise the same metal layer. This metal layer may comprise either the first laminations of a Ni-layer, an AuGe-layer and an Au-layer or second laminations of a Ti-layer, a Pt-layer and an Au-layer. Optionally, it is possible to concurrently form first level interconnections which comprise the same metal layer as the base electrodes 21 and the bottom electrode 23, even the first level interconnections are not illustrated in the drawings.

With reference to FIG. 6C, a silicon dioxide film 30 having a thickness of 100 nanometers is entirely deposited over the substrate. A resist mask is selectively formed on the silicon dioxide film 30. A selective wet etching process is carried out using the resist mask for selectively etching the silicon dioxide film 30. First and second openings 31 and 32 are selectively formed in the silicon dioxide film 30 over the hetero-junction bipolar transistor region 100. A third opening 33 is selectively formed in the silicon dioxide film 30 over the resistive element region 200. A fourth opening 34 is selectively formed in the silicon dioxide film 30 over the metal-insulating-metal capacitor region 300. The resist mask is then removed.

With reference to FIG. 6D, a metal organic vapor phase epitaxy method is carried out using the silicon dioxide film 30 as a mask for selectively forming n+-GaAs layers in the first to fourth openings 31, 32, 33 and 34. The n+-GaAs layers may have a doping concentration of 1×10¹⁹ cm⁻³. The n+-GaAs layers may have a thickness of 100 nanometers.

In the first and second openings 31 and 32, the n+-GaAs layers form the collector electrode contact layers 19. In the third opening 33, the n+-GaAs layer forms the resistive layer 24. In the fourth opening 34, the n+-GaAs layer forms the dielectric polycrystallie layer 25. The used silicon dioxide layer 30 is removed.

The size of the resistive layer 24 is defined by the size of the third opening 33. A sheet resistance of the resistive layer 24 depends on the size of the resistive layer 24. The size of the third opening 33 is decided so that the sheet resistance of the resistive layer 24 is about 65 ohms.

In the fourth opening 34, the n+-GaAs layer is grown in polycrystal on the metal bottom electrode 23. A polycrystal Group III-V compound semiconductor has a high resistivity, for which reason the polycrystalline n+-GaAs layer 25 serves as a dielectric layer of the capacitor 300.

Namely, the collector electrode contact layers 19 of the hetero-junction bipolar transistor 100, the resistive layer 24 of the resistive element 200 and the dielectric polycrystalline layer 25 of the metal-insulating-metal capacitor 300 comprise the same n+-GaAs layer and are concurrently formed in the single process.

With reference to FIG. 6E, a metal layer is selectively formed by a lift-off method, whereby the collector electrodes 22, the resistive element electrodes 26 and the top electrode 27 are concurrently formed. The collector electrodes 22, the resistive element electrodes 26 and the top electrode 27 comprise the same metal layer. This metal layer may comprise the laminations of a Ti-layer, a Pt-layer and an Au-layer.

With reference to FIG. 6F, an inter-layer insulator 28 of silicon dioxide is entirely formed over the substrate 10, so that the hetero-junction bipolar transistor 100, the resistive element 200 and the metal-insulator-metal capacitor 300 are completely buried in the inter-layer insulator 28. A top surface of the inter-layer insulator 28 is planarized. Contact holes are formed in the inter-layer insulator 28, so that the contact holes reach the emitter electrode 20, the base electrodes 21, the collector electrodes 22, the resistive element electrodes 26 and the top electrode 27.

Contact electrode contacts are formed in the contact holes, wherein the contact electrode contacts are in contact with the emitter electrode 20, the base electrodes 21, the collector electrodes 22, the resistive element electrodes 26 and the top electrode 27. Second level interconnections 29 are formed over the planarized top surface of the inter-layer insulator 28, so that the second level interconnections 29 are connected through the contact electrode contacts to the emitter electrode 20, the base electrodes 21, the collector electrodes 22, the resistive element electrodes 26 and the top electrode 27. The monolithic microwave integrated circuit is fabricated.

As described above, the collector electrodes 22 of the hetero-junction bipolar transistor 100 and the bottom electrode 23 of the metal-insulating-metal capacitor 300 comprise the same metal layer and are concurrently formed in the same process. Further, the collector electrode contact layers 19 of the hetero-junction bipolar transistor 100, the resistive layer 24 of the resistive element 200 and the dielectric polycrystalline layer 25 of the metal-insulating-metal capacitor 300 comprise the same n+-GaAs layer and are concurrently formed in the same process. Furthermore, the base electrodes 21 of the hetero-junction bipolar transistor 100, the resistive element electrodes 26 of the resistive element 200 and the top electrode 27 of the metal-insulating-metal capacitor 300 comprise the same metal layer and are concurrently formed in the same process. Those reduce the number of the fabrication processes.

The resistance value of the resistive element 200 is accurately controllable by controlling the size of the third opening in the silicon dioxide mask.

The collector electrodes 22 overly the n+-GaAs collector electrode contact layers 19 with a reduced contact resistance, which reduces a parasitic capacitance. The reduced parasitic capacitance improves high frequency performance of the hetero-junction bipolar transistor.

It is possible as a modification to change the compound of the semiconductors. The monolithic microwave integrated circuit is formed over an InP substrate 10. The hetero-junction bipolar transistor 100 has the emitter electrode 20, the base electrode 21, and the collector electrode 22. The restive element 200 has a p+-InGaAs resistive layer 24 and resistive element electrodes 26, The metal-insulating-metal capacitor 300 has a bottom electrode 23, an n+-InGaAs polycrystalline layer 25, and a top electrode 27, wherein the n+-InGaAs polycrystalline layer 25 is sandwiched between the top and bottom electrodes 27 and 23, so that the n+-InGaAs polycrystalline layer 25 serves as a dielectric, which is a medium capable of maintaining an electric field with no supply of energy from outside source.

An inter-layer insulator 28 of silicon dioxide entirely overlies the substrate, so that the hetero-junction bipolar transistor 100, the restive element 200 and the metal-insulator-metal capacitor 300 are buried in the inter-layer insulator 28. The emitter electrode 20, the base electrode 21, and the collector electrode 22, and the resistive element electrodes 26 as well as the top electrode 27 are electrically connected through contact electrode contacts to second level interconnections 29. The contact electrode contacts are provided in contact holes formed in the inter-layer insulator 28. The second level interconnections 29 extend over the inter-layer insulator 28. The inter-layer insulator 28 has a planarized top surface.

A buffer layer 11 overlies a top surface of the semi-insulating GaAs substrate 10. The buffer layer 11 may have a thickness of 500 nanometers. The buffer layer 11 may comprise an i-InP. An n+-InGaAs sub-collector layer 12 overlies the buffer layer 11. The n+-InGaAs sub-collector layer 12 may have an Si-doping concentration of at least 1×10¹⁸ cm⁻³. The n+-InGaAs sub-collector layer 12 may have a thickness of 500 nanometers. An n-InGaAs collector layer 13 selectively overlies a predetermined region of a top surface of the n+-InGaAs sub-collector layer 12. The n-InGaAs collector layer 13 may have an Si-doping concentration of at least 5×10¹⁶ cm⁻³. The n-InGaAs collector layer 13 may have a thickness of 500 nanometers.

A p+-InGaAs base layer 14 overlies the n-InGaAs collector layer 13. The p+-InGaAs base layer 14 may have a C-doping concentration of at least 3×10¹⁹ cm⁻³. The p+-GaAs base layer 14 may have a thickness of 80 nanometers. An emitter layer 15 selectively overlies a predetermined region of a top surface of the p+-InGaAs base layer 14. The emitter layer 15 may comprise either n-InAlAs doped with Si at 3×10¹⁷ cm⁻³ or n-InP doped with Si at 3×10¹⁷ cm⁻³. The emitter layer 15 may have a thickness of 100 nanometers. A first emitter cap layer 16 selectively overlies a predetermined region of a top surface of the emitter layer 15. The first emitter cap layer 16 may comprise n+-InGaAs doped with Si at 1×10¹⁸ cm⁻³. The first emitter cap layer 16 may have a thickness of 100 nanometers. A second emitter cap layer 17 overlies the first emitter cap layer 16. The second emitter cap layer 17 may comprise n+-InGaAs doped with Si at 1×10¹⁸ cm⁻³. The second emitter cap layer 17 may have a thickness of 100 nanometers.

Collector electrode contact layers 19 are provided on selected regions of the top surface of the n+-InGaAs sub-collector layer 12, so that the collector electrode contact layers 19 are separated from the collector layer 15. The collector electrode contact layers 19 may comprise n+InGaAs doped with Si at 1×10¹⁹ cm⁻³. The collector electrode contact layers 19 may have a thickness of 100 nanometers. Collector electrodes 22 are provided on the collector electrode contact layers 19, so that the collector electrodes 22 are separated from the n-InGaAs collector layer 13. The collector electrodes 22 may comprise either first laminations of a Ni-layer, an AuGe-layer and an Au-layer or second laminations of a Ti-layer, a Pt-layer and an Au-layer. Base electrodes 21 are provided on the selected region of the base layer 14. The base electrodes 21 may comprise laminations of a Ti-layer, a Pt-layer and an Au-layer. An emitter electrode 20 is provided on a top surface of the second emitter cap layer 17. The emitter electrode 20 may comprise tungsten silicide.

The above modified monolithic microwave integrated circuit may be formed by the same fabrication processes as described with reference to FIGS. 6A through 6F.

The above modified monolithic microwave integrated circuit provides the same advantages as described with reference to FIG. 4. Namely, the base electrodes 21 of the hetero-junction bipolar transistor 100 and the bottom electrode 23 of the metal-insulating-metal capacitor 300 comprise the same metal layer and are concurrently formed in the same process. This metal layer may comprise either the first laminations of a Ni-layer, an AuGe-layer and an Au-layer or second laminations of a Ti-layer, a Pt-layer and an Au-layer.

Further, the collector electrode contact layers 19 of the hetero-junction bipolar transistor 100, the resistive layer 24 of the resistive element 200 and the dielectric polycrystalline layer 25 of the metal-insulating-metal capacitor 300 comprise the same n+-InGa layer and are concurrently formed in the same process.

Furthermore, the collector electrodes 22 of the hetero-junction bipolar transistor 100, the resistive element electrodes 26 of the resistive element 200 and the top electrode 27 of the metal-insulating-metal capacitor 300 comprise the same, metal layer and are concurrently formed in the same process. Those reduce the number of the fabrication processes.

The resistance value of the resistive element 200 is accurately controllable by controlling the size of the third opening in the silicon dioxide mask.

The collector electrodes 22 overly the n+-GaAs collector electrode contact layers 19 with a reduced contact resistance, which reduces a parasitic capacitance- The reduced parasitic capacitance improves high frequency performance of the hetero-junction bipolar transistor.

The growth methods, and growth conditions as well as compositions of the individual layers, thicknesses thereof and the conductivity types thereof are optional. Further, the metals and alloys of the electrodes, the sequences of forming the electrodes, the materials of the insulating films and the etching methods are also optional.

It is also possible as a modification that the emitter electrode and either one of the top and bottom electrodes of the capacitor comprise the same layer and are concurrently formed.

The above-described present invention may be applied to other monolithic microwave integrated circuit which has an integration of the hetero-junction bipolar transistor 100 and either one of the resistive element 200 and the metal-insulator-metal capacitor 300.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A monolithically integrated semiconductor device comprising:
a hetero-junction bipolar transistor having at least an electrode contact layer which contacts directly with at least one of collector, base and emitter electrodes; and
at least a passive device having at least a passive device electrode and at least a resistive layer,
wherein said electrode contact layer and said resistive layer comprise the same compound semiconductor layer.

2. The device as claimed in claim i, wherein said passive device electrode and one of said collector, base and emitter electrodes comprises the same metal layer.

3. The device as claimed in claim 1, wherein said at least passive device further comprises:
a resistive element which comprises: at least a resistive element layer; and at least a resistive element electrode; and
a metal-insulator-metal capacitor which comprises: a bottom electrode; a capacitive dielectric layer; and a top electrode.

4. The device as claimed in claim 3, wherein said at least electrode contact layer comprises a base electrode contact layer which contacts directly with said base electrode.

5. The device as claimed in claim 4, wherein said base electrode contact layer, said resistive element layer and said capacitive dielectric layer comprise the same compound semiconductor layer.

6. The device as claimed in claim 5, wherein said base electrode and said bottom electrode comprise the same metal layer.

7. The device as claimed in claim 5, wherein said base electrode and said top electrode comprise the same metal layer.

8. The device, as claimed in claim 5, wherein said base electrode and said resistive element electrodes comprise the same metal layer.

9. The device as claimed in claim 3, wherein said at least electrode contact layer comprises a collector electrode contact layer which contacts directly with said collector electrode.

10. The device as claimed in claim 9, wherein said collector electrode contact layer, said resistive element layer and said capacitive dielectric layer comprise the same compound semiconductor layer.

11. The device as claimed in claim 10, wherein said collector electrode and said bottom electrode comprise the same metal layer.

12. The device as claimed in claim 10, wherein said collector electrode and said top electrode comprise the same metal layer.

13. The device as claimed in claim 10, wherein said collector electrode and said resistive element electrodes comprise the same metal layer.

14. The device as claimed in claim 3, wherein said at least electrode contact layer comprises an emitter electrode contact layer which contacts directly with said emitter electrode.

15. The device as claimed in claim 14, wherein said emitter electrode contact layer, said resistive element layer and said capacitive dielectric layer comprise the same compound semiconductor layer.

16. The device as claimed in claim 15, wherein said emitter electrode and said bottom electrode comprise the same metal layer.

17. The device, as claimed in claim 15, wherein said emitter electrode and said top electrode comprise the same metal layer.

18. The device as claimed in claim 15, wherein said emitter electrode and said resistive element electrodes comprise the same metal layer.

19. The device as claimed in claim 1, wherein said at least passive device further comprises:
a resistive element which comprises at least a resistive element layer; and at least a resistive element electrode.

20. The device as claimed in claim 19, wherein said at least electrode contact layer comprises a base electrode contact layer which contacts directly with said base electrode.

21. The device as claimed in claim 20, wherein said base electrode contact layer and said resistive element layer comprise the same compound semiconductor layer.

22. The device as claimed in claim 21, wherein said base electrode and said resistive element electrodes comprise the same metal layer.

23. The device as claimed in claim 19, wherein said at least electrode contact layer comprises a collector electrode contact layer which contacts directly with said collector electrode.

24. The device as claimed in claim 23, wherein said collector electrode contact layer and said resistive element layer comprise the same compound semiconductor layer.

25. The device as claimed in claim 24, wherein said collector electrode and said resistive element electrodes comprise the same metal layer.

26. The device as claimed in claim 19, wherein said at least electrode contact layer comprises an emitter electrode contact layer which contacts directly with said emitter electrode.

27. The, device as claimed in claim 26, wherein said emitter electrode contact layer and said resistive element layer comprise the same compound semiconductor layer.

28. The device as claimed in claim 27, wherein said emitter electrode and said resistive element electrodes comprise the same metal layer.

29. The device as claimed in claim 1, wherein said at least passive device further comprises:
a metal-insulator-metal capacitor which comprises: a bottom electrode; a capacitive dielectric layer; and a top electrode.

30. The device as claimed in claim 29, wherein said at least electrode contact layer comprises a base electrode contact layer which contacts directly with said base electrode.

31. The device as claimed in claim 30, wherein said base electrode contact layer and said capacitive dielectric layer comprise the same compound semiconductor layer.

32. The device as claimed in claim 31, wherein said base electrode and said bottom electrode comprise the same metal layer.

33. The device as claimed in claim 31, wherein said base electrode and said top electrode comprise the same metal layer.

34. The device as claimed in claim 29, wherein said at least electrode contact layer comprises a collector electrode contact layer which contacts directly with said collector electrode.

35. The device as claimed in claim 34, wherein said collector electrode contact layer and said capacitive dielectric layer comprise the same compound semiconductor layer.

36. The device as claimed in claim 35, wherein said collector electrode and said bottom electrode comprise the same metal layer.

37. The device as claimed in claim 35, wherein said collector electrode and said top electrode comprise the same metal layer.

38. The device as claimed in claim 29, wherein said at least electrode contact layer comprises an emitter electrode contact layer which contacts directly with said emitter electrode.

39. The device as claimed in claim 38, wherein said emitter electrode contact layer and said capacitive dielectric layer comprise the same compound semiconductor layer.

40. The device as claimed in claim 39, wherein said emitter electrode and said bottom electrode comprise the same metal layer.

41. The device as claimed in claim 39, wherein said emitter electrode and said top electrode comprise the same metal layer.

42. A monolithically integrated semiconductor device comprising:
a hetero-junction bipolar transistor having at least an electrode contact layer which contacts directly with at least one of collector, base and emitter electrodes; and
at least a passive device having at least a passive device electrode and at least a resistive layer,
wherein said passive device electrode and one of said collector, base and emitter electrodes comprises the same metal layer.

43. The device as claimed in claim 42, wherein said electrode contact layer and said resistive layer comprise the same compound semiconductor layer.

44. The device as claimed in claim 43, wherein said at least passive device further comprises:
a resistive element which comprises: at least a resistive element layer; and at least a resistive element electrode; and
a metal-insulator-metal capacitor which comprises: a bottom electrode; a capacitive dielectric layer; and a top electrode.

45. The device as claimed in claim 43, wherein said at least passive device further comprises:
a resistive element which comprises: at least a resistive element layer; and at least a resistive element electrode.

46. The device as claimed in claim 43, wherein said at least passive device further comprises:
a metal-insulator-met capacitor which comprises: a bottom electrode; a capacitive dielectric layer; and a top electrode.

47. A monolithically integrated semiconductor device comprising:
a hetero-junction bipolar transistor having at least an electrode contact layer which contacts directly with at least one of collector, base and emitter electrodes;
a resistive element which comprises: at least a resistive element layer; and at least a resistive element electrode; and
a metal-insulator-metal capacitor which comprises: a bottom electrode; a capacitive dielectric layer; and a top electrode,
wherein said electrode contact layer, said resistive element layer and said capacitive dielectric layer comprise the same compound semiconductor layer, and
wherein said resistive element electrode, said top electrode and said at least one of collector, base and emitter electrodes comprises the same metal layer.

48. A method of forming a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer,
wherein said electrode contact layer and said resistive layer are formed concurrently in the same processes.

49. The device as claimed in claim 48, wherein said passive device electrode and one of said collector, base and emitter electrodes are formed concurrently in the same processes.

50. A method of forming a monolithically integrated semiconductor device comprising: a hetero-junction bipolar transistor having at least an electrode contact layer which contacts directly with at least one of collector, base and emitter electrodes; and at least a passive device having at least a passive device electrode and at least a resistive layer,
wherein said passive device electrode and one of said collector, base and emitter electrodes are formed concurrently in the same processes.

51. The device as claimed in claim 50, wherein said electrode contact layer and said resistive layer are formed concurrently in the same processes.

52. A monolithically integrated semiconductor device comprising: a hetero-junction bipolar transistor having at least an electrode contact layer which contacts directly with at least one of collector, base and emitter electrodes; a resistive element which comprises: at least a resistive element layer; and at least a resistive element electrode; and a metal-insulator-metal capacitor which comprises: a bottom electrode; a capacitive dielectric layer; and a top electrode,
wherein said electrode contact layer, said resistive element layer and said capacitive dielectric layer are formed concurrently in the same processes, and
wherein said resistive element electrode, said top electrode and said at least one of collector, base and emitter electrodes are formed concurrently in the same processes.
